(19) United States
(12) Patent Application Publication
(10) Pub. No.: US 2014/0027760 A1
(43) Pub. Date: Jan. 30, 2014

(54) SEMICONDUCTOR DEVICE AND MANUFACTURING METHOD THEREOF

(71) Applicant: Hannstar Display Corporation, New Taipei City (TW)

(72) Inventors: Jung-Fang Chang, Tainan City (TW); Ming-Chieh Chang, Hsinchu County (TW)

(21) Appl. No.: 13/922,266

(22) Filed: Jun. 20, 2013

(30) Foreign Application Priority Data
Jul. 26, 2012 (CN) 201210261610.8

(51) Int. Cl. H01L 29/786; H01L 29/66

(52) U.S. Cl. CPC H01L 29/7869; H01L 29/66742
USPC 257/43; 438/104

(57) ABSTRACT

A semiconductor device and manufacturing method thereof are provided. The manufacturing method of the semiconductor device includes sequentially forming a gate electrode, a gate insulating layer, an oxide semiconductor layer and an etching stop layer on a substrate. The etching stop layer has two contact openings exposing a portion of the oxide semiconductor layer. A metal layer is formed on the etching stop layer, and connected with the oxide semiconductor layer via the contact openings. A half-tone patterned photoresist layer is formed on the metal layer, and is taken as an etching mask to remove the metal layer and the etching stop layer. A thickness of the half-tone patterned photoresist layer is reduced until a second portion of the half-tone patterned photoresist layer is removed, such that a patterned photoresist layer is formed as an etching mask for removing the metal layer and the oxide semiconductor layer.

### CROSS-REFERENCE TO RELATED APPLICATION

This application claims the priority benefit of China application serial no. 201210261610.8, filed on Jul. 26, 2012. The entirety of the above-mentioned patent application is hereby incorporated by reference herein and made a part of this specification.

### BACKGROUND

1. Field of the Invention

The invention relates to a semiconductor device and a manufacturing method thereof, and more particularly to, a semiconductor device with an oxide semiconductor layer, and a manufacturing method thereof.

2. Description of Related Art

Recently, with the rise of environmental awareness, liquid crystal display panels with advantages of low power consumption, good space utilization efficiency, no radiation, and high image quality have become the mainstream of the market. In the past, the liquid crystal display panels mostly adopt an amorphous silicon (a-Si) thin film transistor or a low-temperature polysilicon (LTPS) thin film transistor to be a switch element of each pixel structure. Nevertheless, in recent years, studies have pointed out that: the oxide semiconductor thin film transistor, as compared to the amorphous silicon thin film transistor, has higher carrier mobility; and the oxide semiconductor thin film transistor, as compared to the low-temperature polysilicon thin film transistor, has better threshold voltage (Vth) uniformity. Therefore, the oxide semiconductor thin film transistor has a potential to become a key element of the next generation flat panel display.

In general, the conventional manufacturing process of a semiconductor device having an oxide semiconductor layer substantially involves six masking steps. Firstly, with the first masking step, a gate electrode is formed on a substrate. Then, a gate insulating layer is comprehensively formed on the substrate for covering the gate electrode. Next, with the second masking step, an oxide semiconductor layer is formed on the gate insulating layer above the gate electrode. Furthermore, with the third masking step, an etching stop layer is formed on a portion of the oxide semiconductor layer. Afterward, a metal layer is formed on the etching stop layer; and with the fourth masking step, a source electrode and a drain electrode, which are electrically insulated with each other, are separately defined on two sides of the etching stop layer. Then, an insulating layer is formed on the substrate for covering the source electrode and the drain electrode. After that, with the fifth masking step, a contact window is formed on the insulating layer in order to expose the drain electrode. Finally, with the sixth masking step, a pixel electrode is formed on the substrate, and this pixel electrode fills up the contact window and is electrically connected with the drain electrode. At this point, the manufacturing of the semiconductor device having the oxide semiconductor layer is completed. Nevertheless, the abovementioned manufacturing process of the oxide semiconductor device is complicated, and has high production costs.

In addition, after the etching stop layer is formed, the conventional method must define a pattern for the oxide semiconductor layer via wet etching. Now, an etchant is prone to generate a phenomenon of side etching to the oxide semiconductor layer easily. Furthermore, when the source electrode and the drain electrode are forming in subsequent, the etchant would generate the phenomenon of side etching to a side exposing the oxide semiconductor layer, thus affecting structural reliabilities of subsequent products. Moreover, a side in contact with the oxide semiconductor layer is defined when the metal layer of the source electrode and the drain electrode is deposited; and if it is not etched clean in the subsequent etching steps, then a risk of increasing current leakage or conductance would be generated, thereby affecting electrical reliabilities of the products.

### SUMMARY OF THE INVENTION

The objective of the invention is to provide a semiconductor device and a manufacturing method thereof, capable of reducing production costs and simplifying the manufacturing process.

In order to achieve the abovementioned objective, the invention provides a manufacturing method of a semiconductor device including the following steps. A gate electrode, a gate insulating layer, an oxide semiconductor layer and an etching stop layer are stacked on the substrate. The etching stop layer has two contact openings exposing a portion of the oxide semiconductor layer. A metal layer is formed on the etching stop layer. The metal layer is connected with the oxide semiconductor layer via the contact openings. A portion of the metal layer and the etching stop layer under the metal layer are removed by using a half-tone patterned photoresist layer as an etching mask, so as to expose another portion of the oxide semiconductor layer. A thickness of the half-tone patterned photoresist layer is reduced to form a patterned photoresist layer. The another portion of the metal layer and the another portion of the oxide semiconductor layer exposed outside of the patterned photoresist layer are removed to define a source electrode, a drain electrode and a channel region. The patterned photoresist layer is removed to expose the source electrode and the drain electrode.

In an embodiment of the invention, a material of the oxide semiconductor layer includes Indium-Gallium-Zinc Oxide (IGZO), Indium-Zinc Oxide (IZO), Indium Gallium Oxide (IGO), Zinc Oxide (ZnO), Tin Oxide (SnO), Gallium-Zinc Oxide (GZO), Zinc-Tin Oxide (ZTO), or Indium-Tin Oxide (ITO).

In an embodiment of the invention, a method of reducing the thickness of the half-tone patterned photoresist layer includes plasma ashing.

In an embodiment of the invention, a method of removing the etching stop layer under the portion of the metal layer outside of the half-tone patterned photoresist layer comprises dry etching.

In an embodiment of the invention, the manufacturing method of the semiconductor device further includes forming a passivation layer on the source electrode and the drain electrode after the patterned photoresist layer is removed, wherein the passivation layer covers the source electrode, the drain electrode, the gate insulating layer and the channel region, and the passivation layer has a contact window exposing a portion of the drain electrode.

In an embodiment of the invention, the manufacturing method of the semiconductor device further includes forming a transparent electrode on the passivation layer after the passivation layer is formed, wherein the transparent electrode is electrically connected with the drain electrode through the contact window.

The invention provides a semiconductor device including a substrate, a gate electrode, a gate insulating layer, an oxide semiconductor layer, an etching stop layer, a source electrode and a drain electrode. The gate electrode is disposed on the substrate. The gate insulating layer is disposed on the substrate and covering the gate electrode. The oxide semiconductor layer is disposed on the gate insulating layer, and exposes a portion of the gate insulating layer. The etching stop layer is disposed on the oxide semiconductor layer, and has two contact openings and a channel region. The contact openings expose a portion of the oxide semiconductor layer, and the channel region is located between the contact openings. The source electrode is disposed on the etching stop layer, and connected with the oxide semiconductor layer via one of the contact openings. One side edge the oxide semiconductor layer is inwardly shrunk respect to the source electrode with a first distance, and the first distance is between 0.5 micrometers and 1.0 micrometer. The drain electrode is disposed on the etching stop layer, and connected with the oxide semiconductor layer via other one of the contact openings. The source electrode and the drain electrode are electrically insulated, and the channel region is exposed by the source electrode and the drain electrode. The other side edge the oxide semiconductor layer is inwardly shrunk respect to the drain electrode with a second distance, and the second distance is between 0.5 micrometers and 1.0 micrometer.

In an embodiment of the invention, a material of the oxide semiconductor layer includes Indium-Gallium-Zinc Oxide (IGZO), Indium-Zinc Oxide (IZO), Indium Gallium Oxide (IGO), Zinc Oxide (ZnO), Tin Oxide (SnO), Gallium-Zinc Oxide (GZO), Zinc-Tin Oxide (ZTO), or Indium-Tin Oxide (ITO).

In an embodiment of the invention, the semiconductor device includes a passivation layer covering the source electrode, the drain electrode, the portion of the gate insulating layer and the channel region, wherein the passivation layer has a contact window, and the contact window exposes a portion of the drain electrode.

In an embodiment of the invention, the semiconductor device further includes a transparent electrode is disposed on the passivation layer and electrically connected with the drain electrode via the contact window.

According to the foregoing, the manufacturing of etching stop layer is integrated into the manufacturing process of the oxide semiconductor layer in the invention, and by defining the source electrode, the drain electrode and the channel region through the half-tone patterned photoresist layer, the manufacturing method of the semiconductor device of the invention, in comparison with the conventional manufacturing method of an oxide semiconductor device having a semiconductor layer, may reduce the manufacturing process of one mask (viz. five masking steps), so as to lower the production costs and simplify the manufacturing process, such that a phenomenon of side etching generated by the oxide semiconductor layer is also reduced, and thus the semiconductor device is able to have a favorable structure and electrical reliability.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H are cross-sectional views schematically illustrating a manufacturing method of a semiconductor device according to an embodiment of the invention.

FIG. 1I to FIG. 1J are cross-sectional views schematically illustrating partial steps of a manufacturing method of a semiconductor device according to another embodiment of the invention.

### DETAILED DESCRIPTION OF DISCLOSED EMBODIMENTS

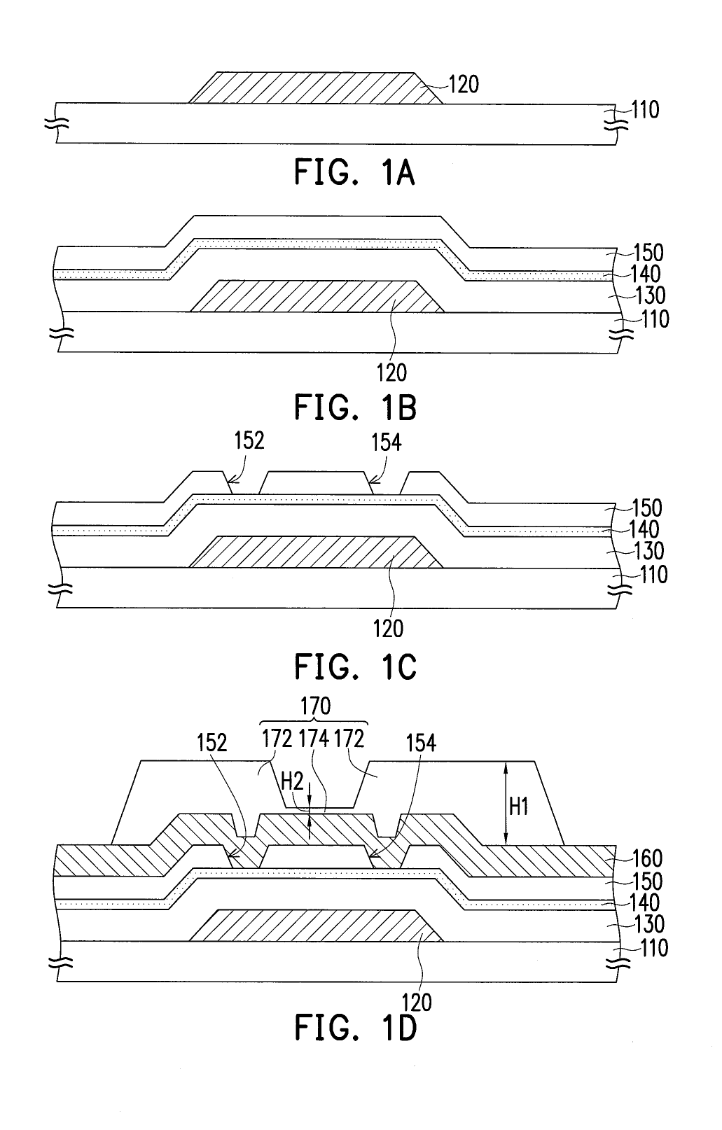

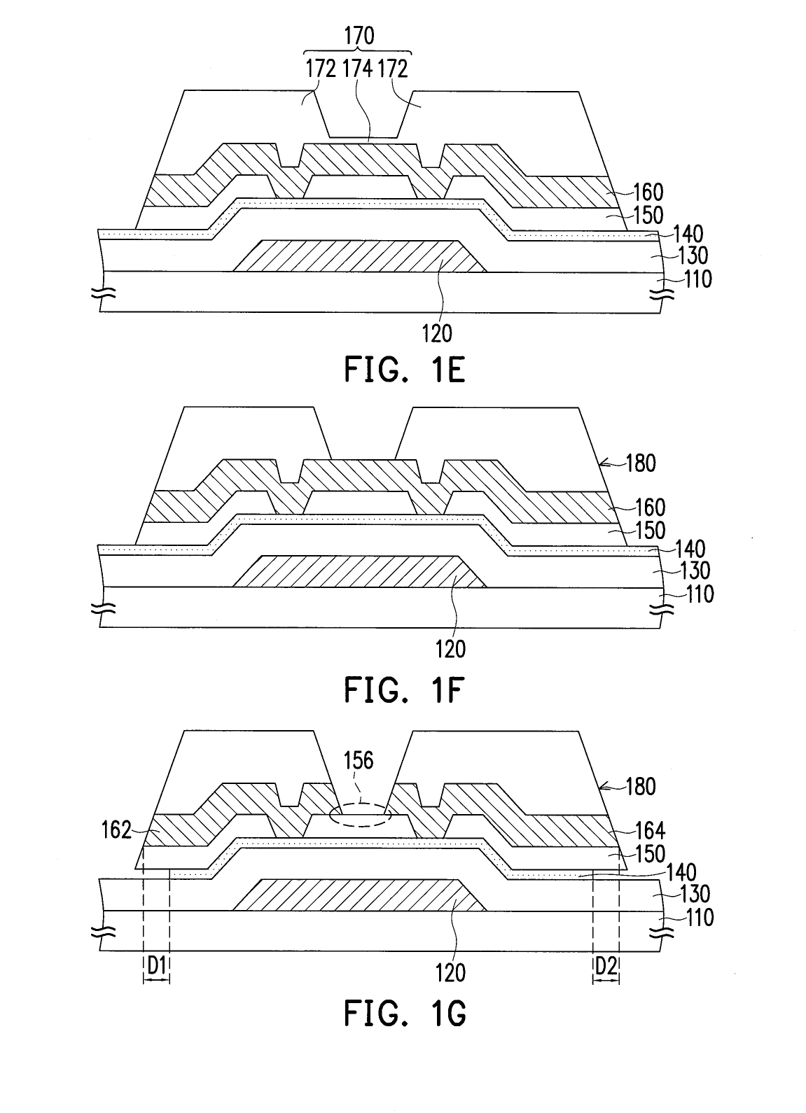

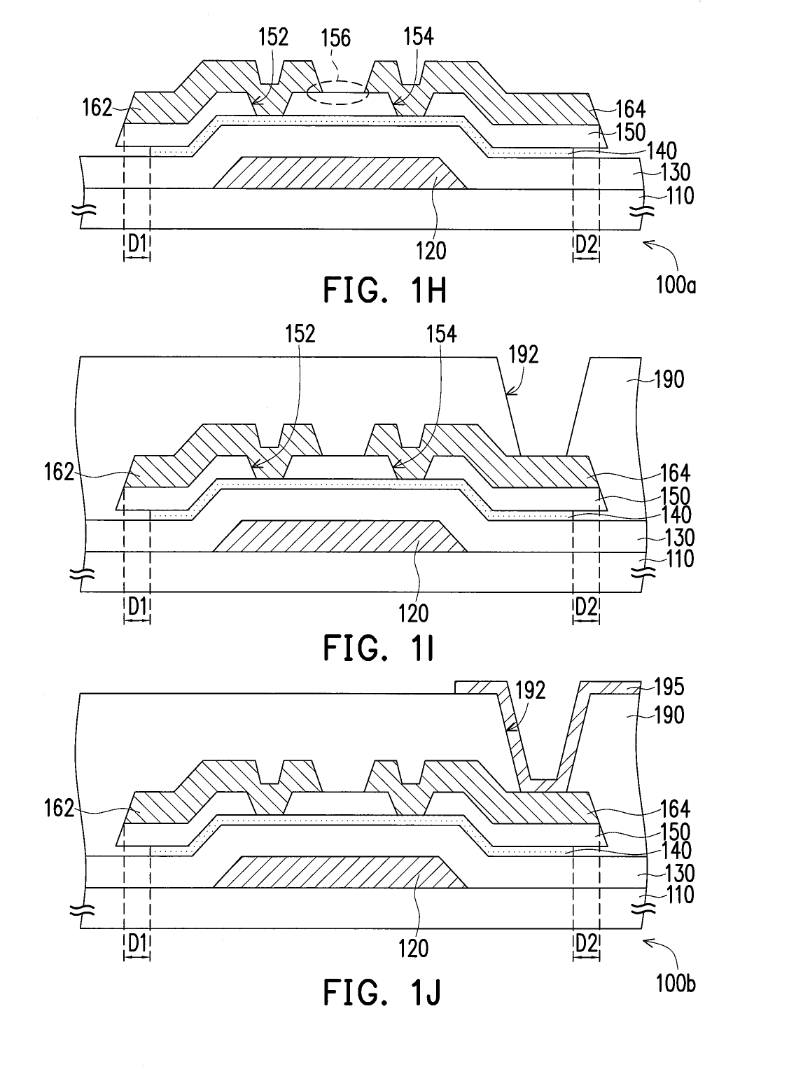

FIG. 1A to FIG. 1H are cross-sectional views schematically illustrating a manufacturing method of a semiconductor device according to an embodiment of the invention. Referring to FIG. 1A, according to the manufacturing method of the semiconductor device in the present embodiment, firstly, a gate electrode 120 is formed on a substrate 110, wherein the gate electrode 120 is disposed on the substrate 110 and exposing a portion of the substrate 110, and a material of the substrate 110 includes glass or plastic, but not limited thereto. Herein, a method of forming the gate electrode 120 is to firstly form a gate metal layer (not shown) on the substrate 110, and then define the gate electrode 120 via performing a first masking step.

Next, referring to FIG. 1B, a gate insulating layer 130, an oxide semiconductor layer 140 and an etching stop layer 150 are sequentially formed and stacked on the substrate 110. The gate insulating layer 130 covers the gate electrode 120 and a portion of the substrate 110. Herein, the oxide semiconductor layer 140 is located between the etching stop layer 150 and the gate insulating layer 130, and a thickness of the oxide semiconductor layer 140 is smaller than a thickness of the etching stop layer 150 and a thickness of the gate insulating layer 130. Favorably, the thickness of the oxide semiconductor layer 140 is, for example, between 300 Angstrom to 500 Angstrom. In addition, a material of the oxide semiconductor layer 140 is, for example, Indium-Gallium-Zinc Oxide (IGZO), Indium-Zinc Oxide (IZO), Indium Gallium Oxide (IGO), Zinc Oxide (ZnO), Tin Oxide (SnO), Gallium-Zinc Oxide (GZO), Zinc-Tin Oxide (ZTO), or Indium-Tin Oxide (ITO), but not limited thereto. Moreover, a method of forming the gate insulating layer 130, the oxide semiconductor layer 140 and the etching stop layer 150 is to adopt, for example, a continuous sedimentation or a non-continuous sedimentation according to a coating means, but is not limited thereto.

Next, referring to FIG. 1C, a second masking step is performed to form two contact openings 152, 154 on the etching stop layer 150, wherein the contact openings 152, 154 expose a portion of the oxide semiconductor layer 140. The objective of forming the contact openings 152, 154 is to enable a source electrode 162 (referring to FIG. 1G) and a drain electrode 164 (referring to FIG. 1G) formed in the subsequent to connect to the oxide semiconductor layer 140 via these contact openings 152, 154. In addition, orthographic projections of the contact openings 152, 154 on the substrate 110 are spaced a distance apart, and are overlapped with an orthographic projection of the gate electrode 120 on substrate 110.

Next, referring to FIG. 1D, a metal layer 160 is formed on the etching stop layer 150. The metal layer 160 covers the etching stop layer 150, and is connected with oxide semiconductor layer 140 via the contact openings 152, 154.

Then, referring to FIG. 1D, a third masking step is performed to form a half-tone patterned photoresist layer 170 on the metal layer 160, wherein the half-tone patterned photoresist layer 170 exposes a portion of the metal layer 160, and the half-tone patterned photoresist layer 170 has a first portion 172 and a second portion 174. Particularly, a thickness H1 of the first portion 172 is greater than a thickness H2 of the second portion 174. Herein, a location of the first portion 172 of the half-tone patterned photoresist layer 170 is corresponded to locations of the source electrode 162 (referring to FIG. 1G) and the drain electrode 164 (referring to FIG. 1G) formed in subsequent, and a location of the second portion 174 of the half-tone patterned photoresist layer 170 is corresponded to a location of a channel region 156 (referring to FIG. 1G) formed in subsequent.

Next, referring to FIG. 1E, the half-tone patterned photoresist layer 170 is taken as an etching mask to remove the portion of the metal layer 160 exposed outside the half-tone patterned photoresist layer 170 and the etching stop layer 150 under the metal layer 160, so as to expose another portion of the oxide semiconductor layer 140. Herein, a method of removing the portion of the metal layer 160 exposed outside the half-tone patterned photoresist layer 170 is, for example, wet etching, and a method of removing the etching stop layer 150 under the portion of the metal layer 160 exposed outside the half-tone patterned photoresist layer 170 is, for example, dry etching. Since the present embodiment has the etching stop layer 150, the oxide semiconductor layer 140 may be protected by the etching stop layer 150 when the metal layer 160 outside the half-tone patterned photoresist layer 170 is etched by an etchant, and thus a generation of a phenomenon of side etching may be effectively avoided. After the portion of the metal layer 160 is removed, the etching stop layer 150 under the metal layer 160 is then removed via the dry etching, which may avoid the use of an etchant, and therefore a phenomenon of side etching generated by the oxide semiconductor layer 140 may be avoid.

Next, referring to FIG. 1E and FIG. 1F at the same time, a thickness of the half-tone patterned photoresist layer 170 is reduced until the second portion 174 is completely removed, so that a patterned photoresist layer 180 is formed. Herein, the patterned photoresist layer 180 exposes another portion of the metal layer 160, wherein a location of the another portion of the metal layer 160 exposed by the patterned photoresist layer 180 is corresponding to a location of the channel region 156 (referring to FIG. 1G) formed in subsequent. In addition, a method of reducing the thickness of the half-tone patterned photoresist layer 180 is, for example, plasma ashing.

Afterward, referring to FIG. 1G, the patterned photoresist layer 180 is taken as an etching mask to remove the another portion of the metal layer 160 and the another portion of the oxide semiconductor layer 140 exposed outside the patterned photoresist layer 180, so that the source electrode 162, the drain electrode 164 and the channel region 156 are defined. Wherein, the source electrode 162 is disposed on the etching stop layer 150, and connected with the oxide semiconductor layer 140 via the contact opening 152. The drain electrode 164 is disposed on the etching stop layer 150, and connected with the oxide semiconductor layer 140 via the contact opening 154. The source electrode 162 and the drain electrode 164 are electrically insulated, and the channel region 156 is exposed by the source electrode 162 and the drain electrode 164. Herein, one side edge the oxide semiconductor layer 140 is inwardly shrunk respect to the source electrode 162 with a first distance D1, and the first distance D1 is between 0.5 micrometers and 1.0 micrometer. The other side edge the oxide semiconductor layer 140 is inwardly shrunk respect to the drain electrode 164 with a second distance D2, and the second distance D2 is between 0.5 micrometers and 1.0 micrometer. Particularly, the etching stop layer 150 of the present embodiment, in addition of being a barrier layer for blocking the etchant from etching the oxide semiconductor layer 140, a portion of the etching stop layer 150 may also be used as a channel region 156.

Finally, referring to FIG. 1H, the patterned photoresist layer 180 is removed to expose the source electrode 162 and the drain electrode 164. At this point, the manufacturing of the semiconductor device 100a is completed, and herein, the semiconductor device 100a is a thin film transistor.

Structurally, referring to FIG. 1H again, the semiconductor device 100a of the present embodiment includes the substrate 110, the gate electrode 120, the gate insulating layer 130, the oxide semiconductor layer 140, the etching stop layer 150, the source electrode 162 and the drain electrode 164. The gate electrode 120 is disposed on the substrate 110. the gate insulating layer 130 is disposed on the substrate 110 and covering the gate electrode 120. The oxide semiconductor layer 140 is disposed on the gate insulating layer 130 and exposing a portion of the gate insulating layer 130. The material of the oxide semiconductor layer is, for example, Indium-Gallium-Zinc Oxide (IGZO), Indium-Zinc Oxide (IZO), Indium Gallium Oxide (IGO), Zinc Oxide (ZnO), Tin Oxide (SnO), Gallium-Zinc Oxide (GZO), Zinc-Tin Oxide (ZTO), or Indium-Tin Oxide (ITO), but not limited thereto. The etching stop layer 150 is disposed on the oxide semiconductor layer 140, and has the contact openings 152, 154 and the channel region 156, wherein the contact openings 152, 154 expose a portion of the oxide semiconductor layer 140, and the channel region 156 is located between the contact openings 152, 154. The source electrode 162 is disposed on the etching stop layer 150, and connected with the oxide semiconductor layer 140 via the contact opening 152. The drain electrode 164 is disposed on the etching stop layer 150, and connected with the oxide semiconductor layer 140 via the contact opening 154. The source electrode 162 and the drain electrode 164 are electrically insulated, and the channel region 156 is exposed by the source electrode 162 and the drain electrode 164. This approach may avoid the drain electrode 164 and the source electrode 162 from causing the oxide semiconductor layer 140 to be over-etched during the etching process when an etching selection ratio between the side etching and the oxide semiconductor layer 140 is too low. In the manufacturing process of the elements, the oxide semiconductor layer 140 is only subjected to chemical erosion when etching the channel region 156 of the etching stop layer 150, whereas in the subsequent process, the oxide semiconductor layer 140 is uninfluenced due to a protection from the etching stop layer 150.

FIG. 1I to FIG. 1J are cross-sectional views schematically illustrating partial steps of a manufacturing method of a semiconductor device according to another embodiment of the invention. The present embodiment has adopted element notations and part of the contents from the previous embodiment, wherein the same notations are used for representing the same or similar elements, and descriptions of the same technical contents are omitted. The descriptions regarding to the omitted part may be referred to the previous embodiment, and thus is not repeated herein.

Referring to FIG. 1J, the semiconductor device 100b of the present embodiment is similar to the semiconductor device 100a of the previous embodiment, and a difference is merely that, the semiconductor device 100b of the present embodiment further includes a passivation layer 190 and a transparent electrode 195. In detail, the passivation layer 190 covers the source electrode 162, the drain electrode 164, a portion of the gate insulating layer 130 and the channel region 156, wherein the passivation layer 190 has a contact window 192, and the contact window 192 exposes a portion of the drain electrode 164. The transparent electrode 195 is disposed on the passivation layer 192, and electrically connected with the drain electrode 164 via the contact window 192. Herein, the semiconductor device 100b is a pixel structure.

In terms of the manufacturing process, the semiconductor device 100b of the present embodiment may adopt substantially the same manufacturing method as the semiconductor device 100a of the previous embodiment; and additionally, a passivation layer 190 is formed on the source electrode 162 and the drain electrode 164 after the step in FIG. 1H, namely after the patterned photoresist layer 180 is removed, referring to FIG. 1I, wherein the passivation layer 190 covers the source electrode 162, the drain electrode 164, the gate insulating layer 130 and the channel region 156, and the passivation layer 190 has a contact window 192 exposing a portion of the drain electrode 164. Then, referring to FIG. 1J, a transparent electrode 195 is formed on the passivation layer 190, wherein the transparent electrode 195 is electrically connected with the drain electrode 164 via the contact window 192. At this point, the manufacturing of the semiconductor device 100b is completed.

In summary, the manufacturing of etching stop layer is integrated into the manufacturing process of the oxide semiconductor layer in the invention, and by defining the source electrode, the drain electrode and the channel region through the half-tone patterned photoresist layer, the manufacturing method of the semiconductor device of the invention, in comparison with the conventional manufacturing method of an oxide semiconductor device having a semiconductor layer, may reduce the manufacturing process of one mask (viz. five masking steps), so as to lower the production costs and simplify the manufacturing process, such that a phenomenon of side etching generated by the oxide semiconductor layer is also reduced, and thus the semiconductor device is able to have a favorable structure and electrical reliability.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A manufacturing method of a semiconductor device comprising:
forming a gate electrode, a gate insulating layer, an oxide semiconductor layer and an etching stop layer stacked on a substrate, wherein the etching stop layer has two contact openings exposing a portion of the oxide semiconductor layer;
forming a metal layer on the etching stop layer, wherein the metal layer is connected with the oxide semiconductor layer via the contact openings;
removing a portion of the metal layer and the etching stop layer under the metal layer by using a half-tone patterned photoresist layer as an etching mask, so as to expose another portion of the oxide semiconductor layer;
reducing a thickness of the half-tone patterned photoresist layer to form a patterned photoresist layer, wherein the patterned photoresist layer exposes another portion of the metal layer;
removing the another portion of the metal layer and the another portion of the oxide semiconductor layer exposed outside the patterned photoresist layer to define a source electrode, a drain electrode and a channel region; and
removing the patterned photoresist layer to expose the source electrode and the drain electrode.

2. The manufacturing method of the semiconductor device as recited in claim 1, wherein a material of the oxide semiconductor layer comprises Indium-Gallium-Zinc Oxide, Indium-Zinc Oxide, Indium Gallium Oxide, Zinc Oxide, Tin Oxide, Gallium-Zinc Oxide, Zinc-Tin Oxide, or Indium-Tin Oxide.

3. The manufacturing method of the semiconductor device as recited in claim 1, wherein a method of reducing the thickness of the half-tone patterned photoresist layer comprises plasma ashing.

4. The manufacturing method of the semiconductor device as recited in claim 1, wherein a method of removing the etching stop layer under the portion of the metal layer outside the half-tone patterned photoresist layer comprises dry etching.

5. The manufacturing method of the semiconductor device as recited in claim 1, further comprising:
forming a passivation layer on the source electrode and the drain electrode after the patterned photoresist layer is removed, wherein the passivation layer covers the source electrode, the drain electrode, the gate insulating layer and the channel region, and the passivation layer has a contact window exposing a portion of the drain electrode.

6. The manufacturing method of the semiconductor device as recited in claim 5, further comprising:
forming a transparent electrode on the passivation layer after the passivation layer is formed, wherein the transparent electrode is electrically connected with the drain electrode via the contact window.

7. A semiconductor device comprising:
a substrate;
a gate electrode disposed on the substrate;
a gate insulating layer disposed on the substrate and covering the gate electrode;
an oxide semiconductor layer disposed on the gate insulating layer, and exposing a portion of the gate insulating layer;
an etching stop layer disposed on the oxide semiconductor layer, and having two contact openings and a channel region, wherein the contact openings exposes a portion of the oxide semiconductor layer, and the channel region is located between the contact openings;
a source electrode disposed on the etching stop layer, and connected with the oxide semiconductor layer via one of the contact openings, wherein one side edge the oxide semiconductor layer is inwardly shrunk respect to the source electrode with a first distance, and the first distance is between 0.5 micrometers and 1.0 micrometer; and
a drain electrode disposed on the etching stop layer, and connected with the oxide semiconductor layer via other one of the contact openings, wherein the source electrode and the drain electrode are electrically insulated, and the channel region is exposed by the source electrode and the drain electrode, the other side edge the oxide semiconductor layer is inwardly shrunk respect to the drain electrode with a second distance, and the second distance is between 0.5 micrometers and 1.0 micrometer.

8. The semiconductor device as recited in claim 7, wherein a material of the oxide semiconductor layer comprises Indium-Gallium-Zinc Oxide, Indium-Zinc Oxide, Indium Gallium Oxide, Zinc Oxide, Tin Oxide, Gallium-Zinc Oxide, Zinc-Tin Oxide, or Indium-Tin Oxide.

9. The semiconductor device as recited in claim 7, further comprising:
a passivation layer covering the source electrode, the drain electrode, the portion of the gate insulating layer and the channel region, wherein the passivation layer has a contact window, and the contact window exposes a portion of the drain electrode.

10. The semiconductor device as recited in claim 9, further comprising:
a transparent electrode disposed on the passivation layer, and electrically connected with the drain electrode via the contact window.
